(19) United States
(12) Patent Application Publication
(10) Pub. No.: US 2004/0114436 A1
(43) Pub. Date: Jun. 17, 2004

(54) Programmable interconnect cell for configuring a field programmable gate array

(75) Inventors: Volker Hecht, Barsinghausen (DE); Robert Ullrich Broze, Santa Cruz, CA (US); Zhezhong Peng, San Jose, CA (US)

Correspondence Address: SIERRA PATENT GROUP, LTD., P O BOX 6149, STATELINE, NV, 89449, US

(73) Assignee: Actel Corporation

(21) Appl. No.: 10/319,782

(22) Filed: Dec. 12, 2002

(51) Int. Cl. G11C 11/34

(52) U.S. Cl. 365/185.28

(57) ABSTRACT

The present invention comprises a programmable interconnect cell switching circuit structure having a control gate potential node, a first floating gate flash transistor with a drain, a source, a floating gate and a control gate connected to the control gate potential node and a second floating gate flash memory transistor having a drain connected to a first programming node, a drain connected to a second programming node, a floating gate connected to the floating gate of the first floating gate flash transistor and a control gate connected to the control gate potential node, whereby either the source or the drain of the first floating gate flash transistor need to be connected outside the cell to ground during the program operation.

### BACKGROUND OF THE INVENTION

1. Field of the Invention

The present invention relates to field programmable gate array (FPGA) integrated circuits. More particularly, the present invention relates to reprogrammable FPGA devices and to programmable interconnect cell devices for configuring a user circuit in a reprogrammable FPGA device.

2. The Prior Art

FPGA integrated circuits are known in the art. FPGA devices may be classified in one of two categories. One category of FPGA devices is one-time programmable and uses elements such as antifuse for making programmable connections. The other category of FPGA devices is programmable and uses transistor switches to make programmable connections.

Typically, an FPGA has an array of logic elements and wiring interconnections with many thousand of programmable interconnect cells so that the FPGA can be configured by the user into an integrated circuit with defined functions. Each programmable interconnect cell, or switch, can connect two circuit nodes in the integrated circuit to make or break a wiring interconnection or to set the function or functions of a logic element.

Reprogrammable FPGA devices include some means for storing program information used to control the programmable elements. Non-volatile memory devices such as EPROMs, EEPROMs, non-volatile RAM and flash memory devices have all been proposed for or used to store programming information in the class of FPGA applications.

An ideal memory device optimizes density, preserves critical memory in a nonvolatile condition, is easy to program and reprogram, and is read quickly. Some non-volatile memory devices meet more of the above requirements than others. For instance, EPROMS are high density, however, they have to be exposed to ultra-violet light for erasure. EEPROMS are electrically byte-erasable, but are less reliable and have the lowest density. Flash memory devices, however, are low cost, high density, low power, high-reliability devices resulting in a high-speed architecture.

There is a need in the art for a programmable interconnect cell having a memory component that is low cost, has high density, has low power consumption and is highly reliable. There is also a need in the art for an FPGA cell having a switch element and a sense element with the forgoing capabilities.

### BRIEF DESCRIPTION OF THE INVENTION

The present invention comprises a programmable interconnect cell switching circuit structure having a control gate potential node, a first floating gate flash transistor with a drain, a source, a floating gate and a control gate connected to the control gate potential node and a second floating gate flash memory transistor having a drain connected to a first programming node, a drain connected to a second programming node, a floating gate connected to the floating gate of the first floating gate flash transistor and a control gate connected to the control gate potential node, whereby either the source or the drain of the first floating gate flash transistor need to be connected outside the cell to ground during the program operation.

A better understanding of the features and advantages of the present invention will be obtained by reference to the following detailed description of the invention and accompanying drawings, which set forth an illustrative embodiment in which the principles of the invention are utilized.

### BRIEF DESCRIPTION OF THE DRAWINGS

FIG. 1 is a simplified schematic diagram of a programmable interconnect cell of the present invention as used in a field programmable gate array structure.

FIG. 2 is a plan view of the cell structure of the programmable interconnect cell of FIG. 1.

FIG. 3 is a cross-sectional view of the programmable interconnect cell along vertical line of the plan view of FIG. 2.

FIG. 4 is a chart showing the representative potentials that can be applied to the programmable interconnect cell of the present invention for the purposes of erasing, programming, and operating the programmable interconnect cell.

### DETAILED DESCRIPTION OF THE INVENTION

Those of ordinary skill in the art will realize that the following description of the present invention is illustrative only and not in any way limiting. Other embodiments of the invention will readily suggest themselves to such skilled persons.

The present invention discloses a programmable interconnect for use in programmable logic circuits. More specifically, the present invention discloses a programmable interconnect for a field programmable gate arrays (FPGAs). Each of the programmable interconnects may have a switch transistor which has its source/drain connected to a first and second circuit node respectively and a sense transistor which forms the memory element of the cell.

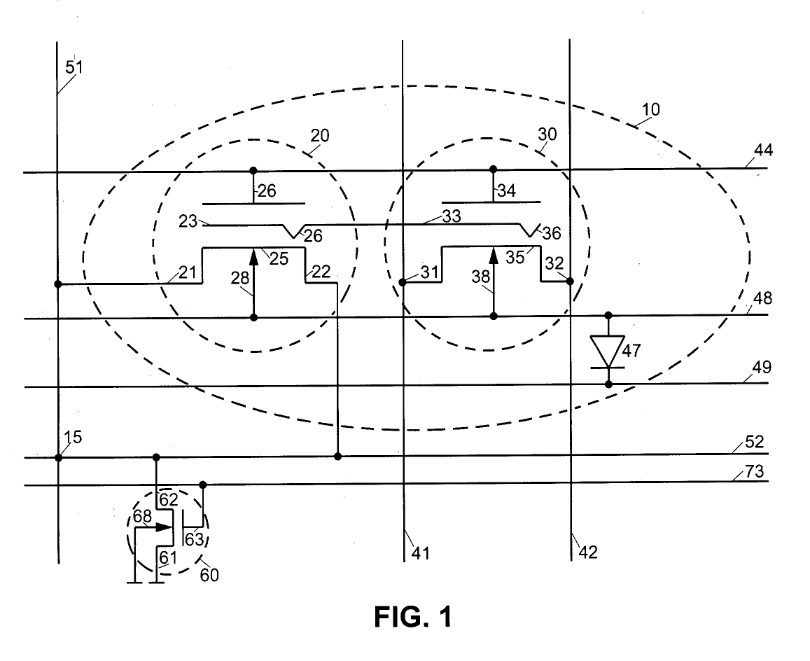

FIG. 1 is a schematic of the programmable interconnect cell 10 of the present invention. Programmable interconnect cell 10 comprises a switch transistor 20 and a sense transistor 30. Switch transistor 20 further comprises a switch source region 21 of the transistor and a switch drain region 22 of the transistor. The programmable interconnect cell 10 makes or breaks a connection at programmable intersection 15 between two routing tracks 51 and 52 through the switch transistor 20, depending on whether switch transistor has been programmed or left unprogrammed according to the requirements of the user circuit. The switch source region 21 is connected to routing track 51 and the switch sense region 22 is connected to the routing track 52. Switch transistor 20 has floating gate 23. Floating gate 23 of switch transistor 20 is connected to the floating gate 33 of sense transistor 30 and will be discussed in greater detail below.

Sense transistor 30 has a source region 31 and a drain region 32. The source 31 of the sense transistor 30 is connected also to a source column line 41, and the drain 32 is connected to a drain column line 42. Column lines 41 and 42 are connected to all source and drain regions of sense transistors 30 in a column. Sense transistor 30 has a floating gate 33. Floating gate 23 of switch transistor 20 and floating gate 33 of sense transistor 30 are connected together.

Switch transistor 20 has a channel region 25. Sense transistor 30 has a channel region 35. There is a Fowler-Nordham tunneling region 26 between the floating gate 23 and channel 25 of the switch transistor 20. There is a Fowler-Nordham tunneling region 36 between the floating gate 33 and channel 35 of the sense transistor 30. Fowler-Nordham tunneling is well known to those of ordinary skill in the art and will not be discussed herein to avoid overcomplicating the disclosure and therefore obscuring the present invention.

Switch transistor control gate 24 and sense transistor control gate 34 are connected to row line 44. Row line 44 connects all control gates 24 and 34 of all cells 10 within a row. Both switch device 20 and sense device 30 are located in a triple p-well 48. Triple p-well 48 is global to all cells 10 within the array. Bulk-connections 28 of all switch transistors 20 and bulk-connections 38 of all sense-transistors 30 are therefore connected to the triple p-well node 48. Triple p-well 48 is located inside an n-well 49, represented in the schematic by a p-well to n-well diode 47.

A grounding transistor 60 has a source region 61, a drain region 62, a gate 63 and a bulk 68. The source region 61 and bulk 68 of this transistor 60 is connected to ground. Gate 63 of transistor 60 is connected to a global erase/program mode signal line 73. At least one of either the source region 21 or the drain region 22 of the switch transistor 20 needs to be connected to a drain region 63 of a grounding transistor 60 over routing structure. As shown in FIG. 1, the drain region 63 of the grounding transistor 60 is connected to routing track 52, which connects to drain region 22 of the switch transistor 20 in order to fulfill this requirement. In another embodiment, a drain region 63 of a grounding transistor 60 may be connected to routing track 51. In yet another embodiment, a drain region 63 of grounding transistor 60 may be connected to routing track 52 and another drain region 63 of another grounding transistor 60 may be connected to routing track 51.

There is one embodiment, however, in which every cell does not need to be coupled to a grounding transistor (on either the source or drain side of the cell). In this embodiment, either the source side or the drain side is hardwired to ground or to the supply voltage, which is grounded during memory operations. In this case, at least one side of the cell is at 0 volts.

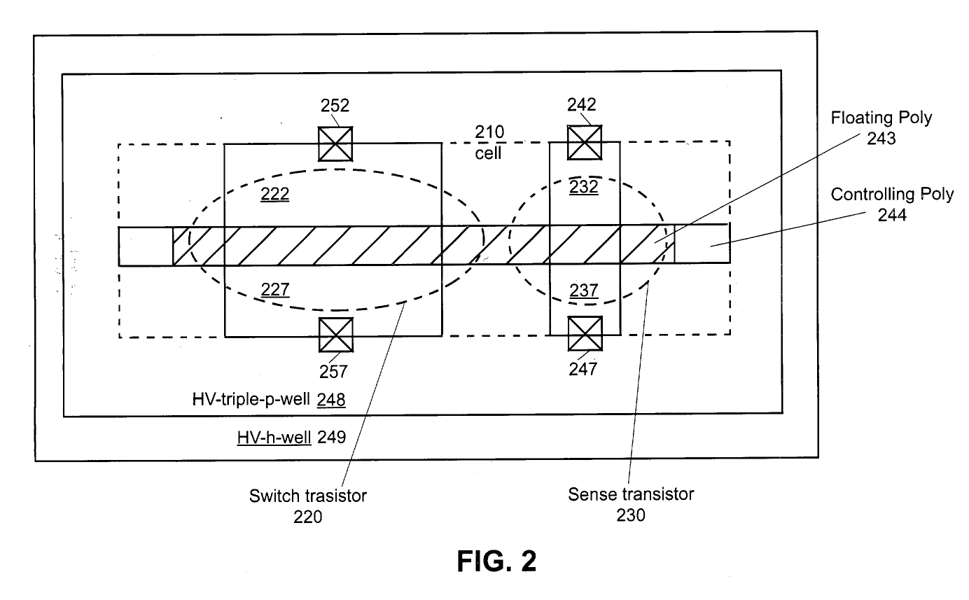

FIG. 2 is a plan view of programmable interconnect element of FIG. 1. FIG.2 further illustrates the layout of programmable interconnect cell 210 having switch transistor 220 and sense transistor 230. Polysilicon floating gate 243 covers both transistor 220 and transistor 230 but does not extend to the edge of cell 210, whereas the self aligned polysilicon control gate 244 covers the whole floating gate 243 and extends to the edge of cell 210. Self-aligned polysilicon control gate 244 connects to polysilicon control gates 244 of adjacent cells 210 within the same row.

Contacts 251 and 252, which form the circuit nodes of the user configurable circuit of the FPGA, are provided to the source/drain regions 221 and 222 of switch transistor 220 for contacting the circuit nodes. Contacts 241 and 242, which form the circuit nodes connected to the source/drain region 231 and 232 of the sense transistor 230. Both switch transistors 220 and sense transistors 230 of all cells are located in the same high-voltage triple p-well 248. High-voltage triple p-well 248 is located inside a high-voltage n-well 249.

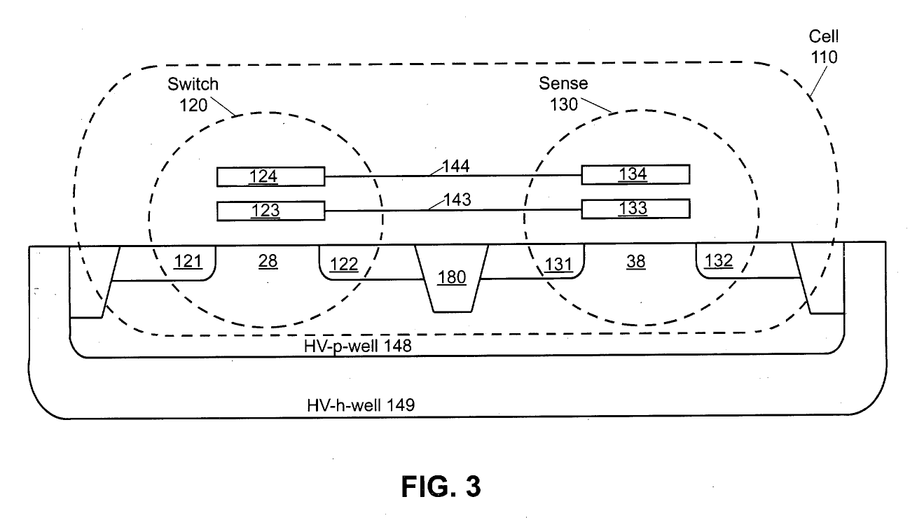

FIG. 3 is a cross-sectional view of the programmable interconnect element cell 110 along vertical axis through both the switch transistor 220 and sense transistor 230 of the programmable interconnect cell 210 of FIG. 2. Programmable interconnect cell 110 comprises high-voltage, triple p-well 148 deposited inside high-voltage n-well 149. All programmable interconnect cells 110 are located in high voltage triple-p-well 148 located in high voltage n-well 149. Programmable interconnect cell 110 includes switch transistor 120 and sense transistor 130 fabricated in high-voltage p-well 148. The source/drain regions 121 and 120 of switch transistor 120, formed by source/drain implants are horizontally isolated from the source/drain regions 131 and 132 of sense transistor 130 by an oxide isolation region 180. Floating gate 123 of switch transistor 120 and floating gate 133 of sense transistor 130 are connected via polysilicon deposit 143. Control gate 124 of switch transistor 120 and control gate 134 of sense transistor 130 are connected via poly-silicon deposit 144.

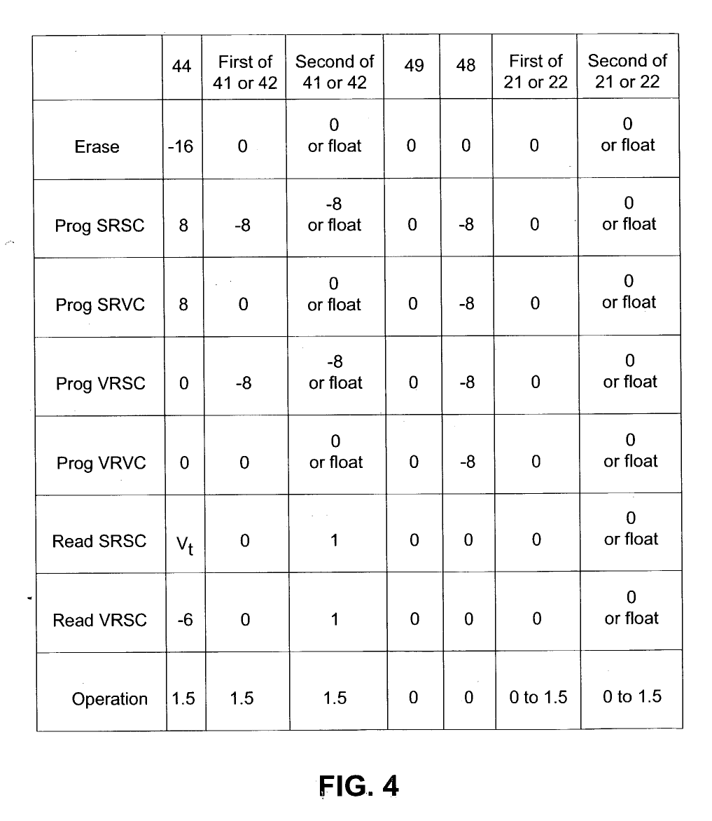

FIG.4 is a table illustrating the respective voltages for erase/programming/read and logic-operation. The erase can be done selective for individual rows or globally for the whole array. Each individual cell can be programmed by selecting rows and columns. Cells can be read individually by selecting rows and columns. During operation of the FPGA, all rows and columns of a part are biased to the same voltage and each individual cell has its individual function in the FPGA circuit, whereby the voltage state of the floating gate of the cell determines whether the cell makes or breaks an interconnect between two nets. Selected rows during erase, programming or read are indicated by the term SR, while unselected rows are indicated by the term UR. Selected columns during programming or read are indicated by the term SC, while unselected columns are indicated by the term UC. The voltages provided in the table are approximate values for switch and sense channel lengths in the order of 0.16 um and tunnel oxide thicknesses in the order of 8-10 nm.

Referring now to FIGS. 1 and 4, the voltages for erasing, programming, reading and the operation of the programmable interconnect cell 10 are illustrated. The n-well node 49 has to be always at a higher or equal voltage than the p-well node 48. This can be most easily achieved by connecting the n-well node 49 to 0V.

For erasing programmable interconnect cell 10, the selected row lines 44 of the programmable interconnect cells 10 are lowered to −16 volts, while the p-well node 49, at least one of the column lines 41 and 42 and at least one of the source 21 and drain 22 regions of the switch 20 are grounded. The second column line 41 or 42 and second source 21 or drain 22 region of the switch transistor 20 can either be also grounded or floating. During this state, electrons from the floating gate node 43 will be removed through the tunneling regions 26 and 36. After erase, when the control-gate voltage will be switched back to 0V, a positive charge will remain on the floating gate node 43. Unselected row-lines stay at 0V during the erase and the floating gate nodes 43 of cells 10 in these rows won't loose electrons and change their state.

To program programmable interconnect cell 10, +8 volts are applied to selected row lines 44 (SR), while all other unselected row lines 44 (UR) are hold at 0V. The p-well node 48 will be biased to −8V. At least one of the column lines 41 and 42 of a selected column (SC) is biased to −8V, while the other of the column lines 41 and 42 can either be biased to −8V or can be floating. At least one of the column lines 41 and 42 of an unselected column (UC) is biased to 0V, while the other of the column lines 41 and 42 of an unselected column (UC) is either biased to 0V or floating. At least one of source region 21 and drain region 22 of each switch 20 in the array has to be biased to 0V by a grounding transistor 60. This is achieved by turning on all transistors 60 by applying a positive voltage of 1.5V to the erase/programming mode signal 73. In this state, electrons will tunnel through tunneling regions 36 from channel 35 of the sense devices 30 to the floating gate of the sense device 33 of selected cells in selected rows and selected columns. Since all channels 35 of unselected columns are at 0V and all control gates of unselected rows are at 0V there is no major tunneling in unselected cells within unselected rows UR or unselected columns UC. After switching back the selected row, selected column and p-well nodes to 0V, there will be a negative charge left on the floating gate node 43 of selected cells, while the state of the floating gate nodes 43 of unselected cells won't have changed during the program operation.

During a read operation, the source column lines 41 of selected columns are connected to 0V, the unselected rows are biased to a negative voltage in the order of −6V in order to turn all sense transistors 30 off independently of their state (initial floating gate voltage). A selected row voltage will be applied. Depending on the initial voltage of the floating gate node 43 of selected cells 10, sense devices 30 will be either turned on or off. An external sense circuit will either bias the drain column line 42 to a voltage in the order of 1V and sense the current or it will force a current into the drain column line 42 of the selected column and sense the voltage at the drain column line 42 and read therefore the state of the cell (programmed or erased, depending on the initial floating gate voltage of the cell). By varying the selected row voltage, the sense trip point of the initial floating gate voltage between the programmed and erased state can be changed.

During the functional operation of the FPGA, all row lines 44 as well as all column lines 41 and 42 can be biased to intermediate voltages like 1.5V in order to optimize the performance of the FPGA.

The described programmable interconnect cell has a typical coupling ratio of 60% between the control gate 44 and the floating gate 43, 35% between the floating gate 43 and the source 21, drain 22 and channel 25 regions of switch transistor 20, 5% between the floating gate 43 and the source 31, drain 32 and channel 35 regions of the sense transistor 30.

While embodiments and applications of this invention have been shown and described, it would be apparent to those skilled in the art that many more modifications than mentioned above are possible without departing from the inventive concepts herein. The invention, therefore, is not to be restricted except in the spirit of the appended claims.

1. A programmable switching circuit structure comprising:
a control gate potential node;
a first floating gate flash memory transistor having a drain, a floating gate, a control gate connected to said control gate potential node, and a source connected to a ground potential; and
a second floating gate flash memory transistor having a drain electrically connected to a first programming node, a drain connected to a second programming node, a floating gate connected to said floating gate of said first floating gate flash transistor, a control gate connected to said control gate potential node.

2. The programmable switching circuit structure of claim 1 wherein said drain of said first floating gate flash memory transistor is floating.

3. The programmable switching circuit structure of claim 1 wherein said source of said first floating gate flash memory transistor is connected to said ground potential through a transistor.

4. The programmable switching circuit structure of claim 1 wherein drain of said first floating gate flash memory transistor is connected to said ground potential through a transistor.

5. A method of programming selected ones of a programmable switching circuit structure arranged in an array of rows and columns comprising:
providing a programming switching structure comprising:
a control gate potential node;
a first floating gate flash transistor having a drain, a floating gate, a control gate connected to said control gate potential node, and a source connected to a ground potential; and
a second floating gate flash memory transistor having a drain electrically connected to a first programming node, a drain connected to a second programming node, a floating gate connected to said floating gate of said first floating gate flash transistor, a control gate connected to said control gate potential node;
applying a ground potential to one of said source and drain of said first floating gate flash transistor;
applying a programming voltage to one of said source and drain of said second floating flash gate transistor; and
applying said programming voltage potential to said control gate potential node.

6. A method of erasing selected rows of a programmable switching circuit structure arranged in an array of rows and columns comprising:
providing a programming switching structure comprising:
a control gate potential node;
a first floating gate flash transistor having a drain, a floating gate, a control gate connected to said control gate potential node, and a source connected to a ground potential; and
a second floating gate flash memory transistor having a drain electrically connected to a first programming node, a drain connected to a second programming node, a floating gate connected to said floating gate of said first floating gate flash transistor, a control gate connected to said control gate potential node;
applying a ground potential to each of said source and said drain of said first floating gate flash transistor;
applying a ground potential to each of said source and said drain of said second floating gate flash transistor; and
applying an erasing potential to said control gate potential node.

7. A method of reading selected ones of a programmable switching circuit structure arranged in an array of rows and columns comprising:
providing a programming switching structure comprising:
a control gate potential node;
a first floating gate flash transistor having a drain, a floating gate, a control gate connected to said control gate potential node, and a source connected to a ground potential; and
a second floating gate flash memory transistor having a drain electrically connected to a first programming node, a drain connected to a second programming node, a floating gate connected to said floating gate of said first floating gate flash transistor, a control gate connected to said control gate potential node;
applying a ground potential to each of said source and said drain of said first floating gate flash transistor;
applying a ground potential to said source of said second floating gate flash transistor and applying a ground potential to said drain of said second floating gate flash transistor; and
applying a reading potential to said control gate potential node.

8. A method of operating selected ones of a programmable switching circuit structure arranged in an array of rows and columns comprising:
providing a programming switching structure comprising:
a control gate potential node;
a first floating gate flash transistor having a drain, a floating gate, a control gate connected to said control gate potential node, and a source connected to a ground potential; and
a second floating gate flash memory transistor having a drain electrically connected to a first programming node, a drain connected to a second programming node, a floating gate connected to said floating gate of said first floating gate flash transistor, a control gate connected to said control gate potential node;
applying either a ground potential and operating potential to each of said source and said drain of said first floating gate flash transistor;
applying an operating potential to said source of said second floating gate flash transistor and applying an operating potential to said drain of said second floating gate flash transistor; and
applying an operating potential to said control gate potential node.
